(19) United States
(12) Patent Application Publication
(10) Pub. No.: US 2025/0248223 A1
(43) Pub. Date: Jul. 31, 2025

(54) DISPLAY APPARATUS AND METHOD OF MANUFACTURING THE SAME

(71) Applicant: Samsung Display Co., LTD., Yongin-si (KR)

(72) Inventors: Hyuneok SHIN, Yongin-si (KR); Jonghee PARK, Yongin-si (KR); Byungsoo SO, Yongin-si (KR); Seungyong SONG, Yongin-si (KR); Changhee LEE, Yongin-si (KR); Sungsoon IM, Yongin-si (KR); Keunho JANG, Yongin-si (KR)

(21) Appl. No.: 18/795,788

(22) Filed: Aug. 6, 2024

(30) Foreign Application Priority Data
Jan. 26, 2024 (KR) 10-2024-0012446

(51) Int. Cl. H10K 59/122; H10K 59/12; H10K 59/80

(52) U.S. Cl. CPC H10K 59/122; H10K 59/1201; H10K 59/80521

(57) ABSTRACT

Provided are a display apparatus and a method of manufacturing the display apparatus. The display apparatus includes a substrate, a first sub-pixel electrode over the substrate, a conductive bank layer disposed on the first sub-pixel electrode and including a first opening overlapping the first sub-pixel electrode, a first intermediate layer overlapping the first sub-pixel electrode and contacting the first sub-pixel electrode through the first opening of the conductive bank layer, and an opposite electrode covering the first intermediate layer and the conductive bank layer. The first intermediate layer includes a first portion in a center of the first intermediate layer and a second portion extending peripherally from the first portion. An upper surface of the second portion includes a slope surface sloped toward an upper surface of the substrate with respect to an extension direction.

### CROSS-REFERENCE TO RELATED APPLICATION

This application claims priority to Korean Patent Application No. 10-2024-0012446, filed on Jan. 26, 2024, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the display apparatus.

### 2. Description of the Related Art

A display apparatus visually displays data. A display apparatus may display images using light-emitting diodes. Display apparatuses have been variously purposed, and various attempts have been made to design a display apparatus with improved quality.

### SUMMARY

One or more embodiments include a display apparatus capable of displaying high-quality images and a method of manufacturing the display apparatus. However, such a technical problem is an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a first sub-pixel electrode over the substrate, a conductive bank layer disposed on the first sub-pixel electrode and including a first opening overlapping the first sub-pixel electrode, a first intermediate layer overlapping the first sub-pixel electrode and contacting the first sub-pixel electrode through the first opening of the conductive bank layer, and an opposite electrode covering the first intermediate layer and the conductive bank layer, wherein the first intermediate layer includes a first portion in a center of the first intermediate layer and a second portion extending peripherally from the first portion, and an upper surface of the second portion includes a slope surface sloped toward an upper surface of the substrate with respect to an extension direction of the second portion.

The slope surface of the second portion may be inclined at an angle of about 15° to about 45° with respect to the upper surface of the substrate.

A vertical distance from the upper surface of the substrate to an upper surface of the first portion of the first intermediate layer may be greater than a vertical distance from the upper surface of the substrate to the upper surface of the second portion of the first intermediate layer.

The display apparatus may further include an insulating layer disposed between a peripheral portion of the first sub-pixel electrode and the conductive bank layer and including an opening overlapping the first opening.

At least a portion of the first intermediate layer may be disposed on an upper surface of the insulating layer.

A width of the first opening of the conductive bank layer may be greater than a width of the opening of the insulating layer.

An edge of the first intermediate layer may be in contact with the conductive bank layer.

An edge of the first intermediate layer may be adjacent to the conductive bank layer.

The opposite electrode may continuously cover at least a portion of an upper surface of the conductive bank layer, at least a portion of a lateral surface of the conductive bank layer, and an upper surface of the first intermediate layer.

The display apparatus may further include a second sub-pixel electrode over the substrate, and a second intermediate layer overlapping the second sub-pixel electrode and contacting the second sub-pixel electrode through a second opening of the conductive bank layer, wherein the opposite electrode may continuously cover the first intermediate layer, the conductive bank layer, and the second intermediate layer.

According to one or more embodiments, a method of manufacturing a display apparatus includes forming a first sub-pixel electrode over a substrate, forming a conductive bank layer including a first opening overlapping the first sub-pixel electrode, forming a first intermediate layer overlapping the first sub-pixel electrode and contacting the first sub-pixel electrode through the first opening of the conductive bank layer, and forming an opposite electrode covering the first intermediate layer and the conductive bank layer, wherein the first intermediate layer includes a first portion in a center of the first intermediate layer and a second portion extending peripherally from the first portion, and an upper surface of the second portion includes a slope surface sloped toward an upper surface of the substrate with respect to an extension direction of the second portion.

The method may further include forming an insulating layer disposed between a peripheral portion of the first sub-pixel electrode and the conductive bank layer and including an opening overlapping the first opening, wherein a width of the first opening of the conductive bank layer may be greater than a width of the opening of the insulating layer.

The forming of the conductive bank layer may include forming a preliminary conductive bank layer including a first conductive layer and a second conductive layer on the first conductive layer, and removing the second conductive layer of the preliminary conductive bank layer, wherein the second conductive layer may include a tip extending in a direction from a point where a lateral surface of the first conductive layer meets a bottom surface of the second conductive layer.

The removing of the second conductive layer may be performed after the forming of the first intermediate layer.

The forming of the first intermediate layer may include forming the first intermediate layer and a first dummy intermediate layer, forming a first sacrificial layer on the first intermediate layer, and forming a first dummy sacrificial layer on the first dummy intermediate layer, forming a first photoresist pattern overlapping the first sub-pixel electrode, etching the first dummy intermediate layer and the first dummy sacrificial layer using the first photoresist pattern as a mask, and removing the first photoresist pattern.

The method may further include removing the first sacrificial layer.

The method may further include forming a second sub-pixel electrode over the substrate, and forming a second intermediate layer overlapping the second sub-pixel electrode and contacting the second sub-pixel electrode through a second opening of the conductive bank layer, wherein the opposite electrode may continuously cover the first intermediate layer, the conductive bank layer, and the second intermediate layer.

The forming of the second intermediate layer may include forming the second intermediate layer and a second dummy intermediate layer, forming a second sacrificial layer on the second intermediate layer, and forming a second dummy sacrificial layer on the second dummy intermediate layer, forming a second photoresist pattern overlapping the second sub-pixel electrode, etching the second dummy intermediate layer and the second dummy sacrificial layer using the second photoresist pattern as a mask, and removing the second photoresist pattern.

The method may further include removing the second sacrificial layer, wherein the removing of the second sacrificial layer may be simultaneously performed with the removing of the first sacrificial layer.

An edge of the first intermediate layer may be in contact with or adjacent to the conductive bank layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are schematic perspective views of a display apparatus according to an embodiment;

FIG. 2 is a schematic equivalent circuit diagram of a light-emitting diode corresponding to one of sub-pixels of the display apparatus and a sub-pixel circuit connected to a relevant light-emitting diode according to an embodiment;

FIG. 3 is a schematic cross-sectional view of a display apparatus according to an embodiment and illustrates a structure corresponding to a first light-emitting diode provided to the display apparatus;

FIG. 4 is a schematic cross-sectional view of a stack structure of a first light-emitting diode included in the display apparatus according to an embodiment;

FIG. 5 is a schematic cross-sectional view of a display apparatus according to another embodiment;

FIG. 6 is a plan view of a display apparatus according to an embodiment;

FIG. 7 is a cross-sectional view of the display apparatus taken along line X-X′ of FIG. 6 according to an embodiment; and

FIGS. 8A to 8J are schematic cross-sectional views corresponding to a process of manufacturing a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described herein in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element illustrated in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

In the present specification, “A and/or B” means A or B, or A and B. In the present specification, “at least one of A and B” means A or B, or A and B.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

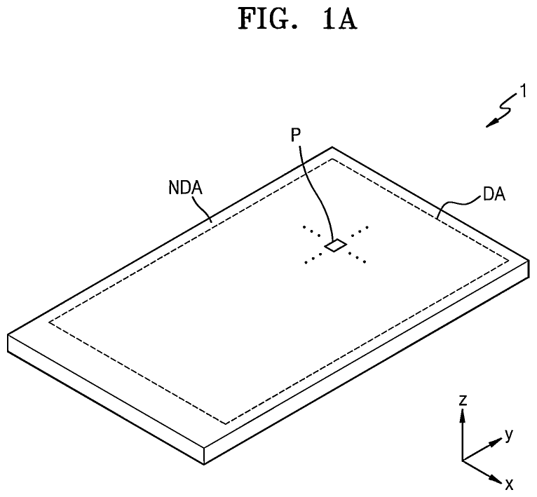

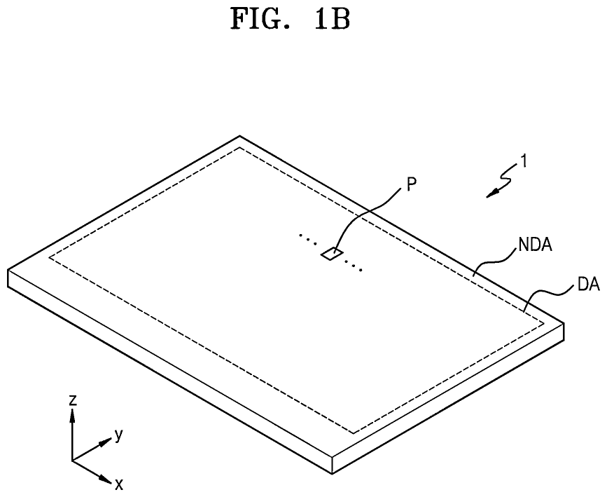

FIGS. 1A and 1B are schematic perspective views of a display apparatus 1 according to an embodiment.

Referring to FIGS. 1A and 1B, the display apparatus 1 may include a display area DA and a non-display area NDA outside the display area DA. The display area DA may be configured to display images through sub-pixels P arranged in the display area DA. The non-display area NDA is arranged outside the display area DA and does not display images. The non-display area NDA may surround the display area DA entirely. A driver and the like configured to provide electrical signals or power to the display area DA may be arranged in the non-display area NDA. A pad may be arranged in the non-display area NDA, wherein electronic elements or a printed circuit board may be electrically connected to the pad.

In an embodiment, although FIG. 1A illustrates that the display area DA has a polygon shape (e.g., a quadrangle) in which a length of the polygon shape in an x direction is less than a length of the polygon shape in a y direction, FIG. 1B illustrates that the display area DA has a polygon shape (e.g., a quadrangle) in which a length of the polygon shape in the y direction is less than a length of the polygon shape in the x direction in another embodiment. Although FIGS. 1A and 1B show the display area DA has an approximately quadrangle shape, the disclosure is not limited thereto. In another embodiment, the display area DA may have various shapes such as, for example, an N-gon (where N is a natural number of 3 or more), a circle, or an ellipse. Although it is illustrated in FIGS. 1A and 1B that the display area DA has a shape in which a corner of the display area DA includes a vertex at which a straight line meets a straight line, the display area DA may have a polygon having round corners in another embodiment.

Hereinafter, for convenience of description, although the case where the display apparatus 1 is a smartphone is described, the display apparatus 1 according to the disclosure is not limited thereto. The display apparatus 1 is applicable to various products including televisions, notebook computers, monitors, advertisement boards, Internet of things (IoTs) as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In some aspects, the display apparatus 1 according to an embodiment is applicable to wearable devices including smartwatches, watchphones, glasses-type displays, and head-mounted displays (HMDs). In some aspects, in an embodiment, the display apparatus 1 is applicable to a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

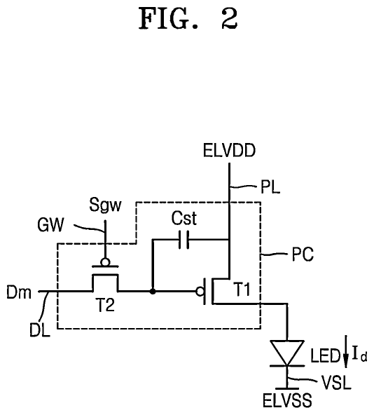

FIG. 2 is a schematic equivalent circuit diagram of a light-emitting diode LED corresponding to one of sub-pixels of the display apparatus and a sub-pixel circuit connected to a relevant light-emitting diode LED according to an embodiment.

Referring to FIG. 2, the light-emitting diode LED may be electrically connected to a sub-pixel circuit PC, and the sub-pixel circuit PC may include a first transistor T1, a second transistor T2, and a storage capacitor Cst. A sub-pixel electrode (e.g., an anode) of the light-emitting diode LED may be electrically connected to the first transistor T1, and an opposite electrode (e.g., a cathode) may be electrically connected to an auxiliary line VSL and may receive a voltage corresponding to a common voltage ELVSS through the auxiliary line VSL.

The second transistor T2 is configured to transfer a data signal Dm to the first transistor T1 according to a scan signal Sgw input through a scan line GW, wherein the data signal Dm is input through a data line DL.

The storage capacitor Cst may be connected to the second transistor T2 and a driving voltage line PL and configured to store a voltage corresponding to a difference between a voltage transferred from the second transistor T2 and a driving voltage ELVDD supplied to the driving voltage line PL.

The first transistor T1 may be connected to the driving voltage line PL and the storage capacitor Cst and configured to control a driving current I_{d} according to the voltage stored in the storage capacitor Cst, the driving current I_{d} flowing from the driving voltage line PL to the light-emitting diode LED. The light-emitting diode LED may be configured to emit light having a preset brightness corresponding to the driving current I_{d}.

Although it is described with reference to FIG. 2 that the sub-pixel circuit PC includes two transistors and one storage capacitor, the disclosure is not limited thereto. In another embodiment, the sub-pixel circuit PC may include three or more transistors and two or more capacitors.

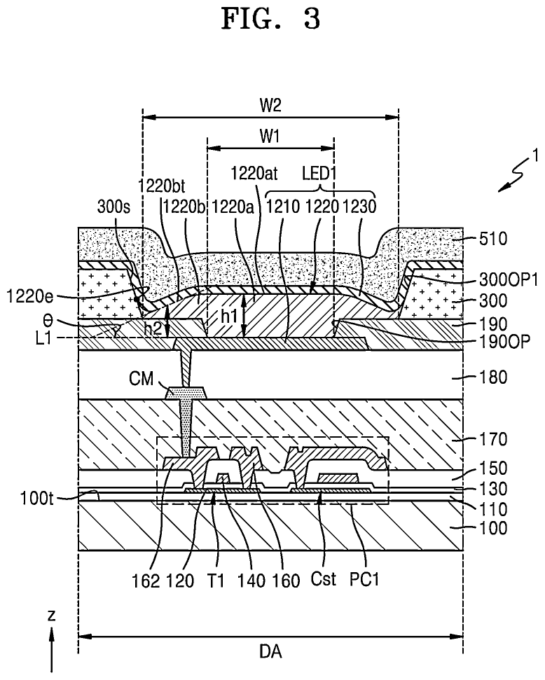

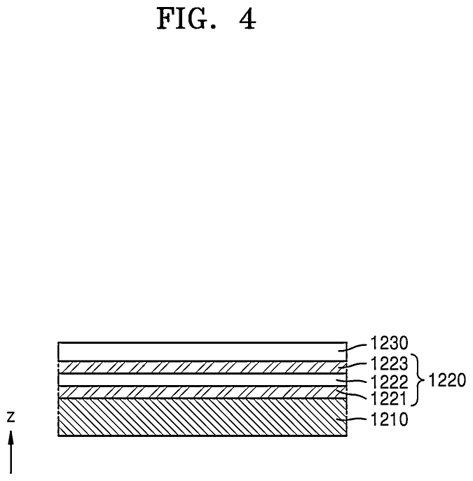

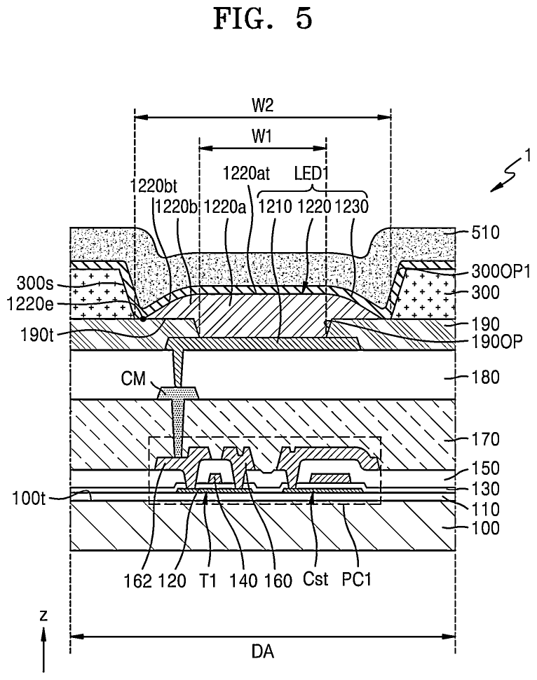

FIG. 3 is a schematic cross-sectional view of the display apparatus 1 according to an embodiment and illustrates a cross-sectional structure corresponding to a first light-emitting diode LED1 provided to the display apparatus 1. FIG. 4 is a schematic cross-sectional view of a stack structure of the first light-emitting diode LED1 included in the display apparatus 1 according to an embodiment. In some aspects, FIG. 5 is a schematic cross-sectional view of the display apparatus 1 according to another embodiment and illustrates a modified embodiment of FIG. 3.

Referring to FIG. 3, the display area DA of the display apparatus 1 may include the first light-emitting diode LED1 disposed over the substrate 100. The first light-emitting diode LED1 may include a first sub-pixel electrode 1210, a first intermediate layer 1220 on the first sub-pixel electrode 1210, and an opposite electrode 1230 on the first intermediate layer 1220. The first light-emitting diode LED1 may be configured to emit light of a first color.

The substrate 100 may include glass or polymer resin. In an embodiment, the substrate 100 may have a structure in which a base layer including polymer resin and a barrier layer are stacked. The polymer resin may include a polymer resin such as, for example, polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose tri acetate (TAC), cellulose acetate propionate (CAP), and the like.

The first light-emitting diode LED1 may be electrically connected to a first sub-pixel circuit PC1 disposed between the substrate 100 and the first light-emitting diode LED1. As described herein with reference to FIG. 2, the first sub-pixel circuit PC1 may include the transistor and the storage capacitor. In an embodiment, FIG. 3 illustrates the first transistor T1 and the storage capacitor Cst of the first sub-pixel circuit PC1.

A buffer layer 110 may be disposed between the substrate 100 and the first transistor T1. The buffer layer 110 may prevent impurities from penetrating a semiconductor layer of a transistor (e.g., the first transistor T1). The buffer layer 110 may include an inorganic insulating material such as, for example, silicon nitride, silicon oxynitride, and silicon oxide, and include a single layer or a multi-layer including the described inorganic insulating materials.

The first transistor T1 may include a first semiconductor layer 120 and a first gate electrode 140, wherein the first semiconductor layer 120 is on the buffer layer 110, and the first gate electrode 140 overlaps a channel region of the first semiconductor layer 120. The first semiconductor layer 120 may include a silicon-based semiconductor material, for example, polycrystalline silicon. Alternatively, or additionally, the first semiconductor layer 120 may include an oxide-based semiconductor material. The first semiconductor layer 120 may include the channel region, a first region, and a second region, the first region and the second region being on two opposite sides of the channel region. The first region and the second region are regions including impurities of higher concentration than impurities of the channel region, or conductive regions. One of the first region and the second region may correspond to a source region, and the other may correspond to a drain region.

A gate insulating layer 130 may be disposed between the first semiconductor layer 120 and the first gate electrode 140. The gate insulating layer 130 may include an inorganic insulating material such as, for example, silicon nitride, silicon oxynitride, and silicon oxide and include a single layer or a multi-layer including the described inorganic insulating materials.

A first interlayer insulating layer 150 may be disposed on the first gate electrode 140. The first interlayer insulating layer 150 may include an inorganic insulating material such as, for example, silicon nitride, silicon oxynitride, and silicon oxide, and include a single layer or a multi-layer including the described inorganic insulating materials.

A source electrode 160 and a drain electrode 162 may be respectively electrically connected to the source region and the drain region of the first semiconductor layer 120. A first organic insulating layer 170 may be disposed on the source electrode 160 and the drain electrode 162. The first organic insulating layer 170 may include an organic insulating material. The storage capacitor Cst may include at least two capacitor electrodes overlapping each other. In an embodiment described with reference to FIG. 3, a first capacitor electrode (not illustrated) may be on the same layer as the first semiconductor layer 120, a second capacitor electrode (not illustrated) may be on the same layer as the first gate electrode 140, and/or a third capacitor electrode (not illustrated) may be on the same layer as the drain electrode 162. Each of the source electrode 160 and the drain electrode 162 may include aluminum (Al), copper (Cu), and/or titanium (Ti) and include a single layer or a multi-layer including the described materials.

A connection metal CM may be disposed on the first organic insulating layer 170, and the first sub-pixel electrode 1210 of the first light-emitting diode LED1 may be connected to the connection metal CM through a contact hole formed in a second organic insulating layer 180. The connection metal CM may electrically connect the first sub-pixel circuit PC1 to the first sub-pixel electrode 1210 of the first light-emitting diode LED1. The first organic insulating layer 170 may include an organic insulating material such as, for example, acryl, benzocyclobutene (BCB), polyimide, or hexamethyldisiloxane (HMDSO). The connection metal CM may include aluminum (Al), copper (Cu), and/or titanium (Ti), and include a single layer or a multi-layer including the described materials.

In another embodiment, the first sub-pixel electrode 1210 of the first light-emitting diode LED1 may be directly connected to the first sub-pixel circuit PC1. In another embodiment, a plurality of connection metals disposed on different layers may be disposed between the first sub-pixel electrode 1210 of the first light-emitting diode LED1 and the first sub-pixel circuit PC1. The first sub-pixel electrode 1210 of the first light-emitting diode LED1 may be electrically connected to the first sub-pixel circuit PC1 through the plurality of connection metals.

The first sub-pixel electrode 1210 of the first light-emitting diode LED1 may be disposed on the second organic insulating layer 180. The second organic insulating layer 180 may include an organic insulating material such as, for example, acryl, benzocyclobutene (BCB), polyimide, or hexamethyldisiloxane (HMDSO).

The first sub-pixel electrode 1210 may include metal and/or a conductive oxide. As an example, the first sub-pixel electrode 1210 may include a reflective layer and a layer under and/or on the reflective layer, wherein the reflective layer includes Ag, Mg, Al, Pt, Pd, Au, Ni, Nd, Ir, Cr, or compounds thereof, and the layer includes ITO, IZO, ZnO, or In₂O₃. In an embodiment, the first sub-pixel electrode 1210 may have a structure of an ITO layer, an Ag layer, and an ITO layer that are sequentially stacked.

The conductive bank layer 300 may be disposed over the first sub-pixel electrode 1210 with an insulating layer 190 between the conductive bank layer 300 and the first sub-pixel electrode 1210. The conductive bank layer 300 may include a first opening 300OP1 passing through the conductive bank layer 300 in a thickness direction of the conductive bank layer 300. The first opening 300OP1 of the conductive bank layer 300 may overlap the first sub-pixel electrode 1210.

The conductive bank layer 300 may be electrically insulated from the first sub-pixel electrode 1210 by the insulating layer 190. The insulating layer 190 may be entirely formed over the substrate 100. As an example, the insulating layer 190 may be in direct contact with an upper surface of an outer portion of the first sub-pixel electrode 1210 and the upper surface of the second organic insulating layer 180 on which the first sub-pixel electrode 1210 is not disposed. The insulating layer 190 may cover the lateral surface (that is, the edge) of the first sub-pixel electrode 1210. The insulating layer 190 may include an inorganic insulating material. In the case where the insulating layer 190 includes an inorganic insulating material, deterioration of the quality of the light-emitting diode due to a gas emitted from the insulating layer 190 during the process of manufacturing the display apparatus may be prevented or reduced compared to a case where the insulating layer 190 includes an organic insulating material.

The insulating layer 190 may include an inorganic insulating material such as, for example, silicon nitride, silicon oxynitride, and silicon oxide, and include a single-layered structure or a multi-layered structure including the described inorganic insulating materials. The insulating layer 190 may include an opening 190OP overlapping the first opening 300OP of the conductive bank layer 300 and the first sub-pixel electrode 1210. A width W1 of the opening 190OP of the insulating layer 190 may be less than a width W2 of the first opening 300OP1.

The first intermediate layer 1220 may be in direct contact with the first sub-pixel electrode 1210 through the opening 190OP of the insulating layer 190. The first intermediate layer 1220 may include a first portion 1220a at a center of the first intermediate layer 1220, and a second portion 1220b extending peripherally from the first portion 1220a. For example, the second portion 1220b may extend in a direction (e.g., X direction, Y direction) away from the first portion 1220a and the center of the first intermediate layer 1220. The first portion 1220a may be a central portion of the first intermediate layer 1220, and the second portion 1220b may be a peripheral portion of the first intermediate layer 1220. In some aspects, the second portion 1220b may be referred to as an outer portion of the first intermediate layer 1220. The first portion 1220a of the first intermediate layer 1220 may overlap and be in contact with the first sub-pixel electrode 1210, and the second portion 1220b may extend on the insulating layer 190 and overlap and be in contact with the insulating layer 190. At least a portion of the first intermediate layer 1220, for example, the second portion 1220b may be disposed on the upper surface of the insulating layer 190.

The first intermediate layer 1220 disposed between the opposite electrode 1230 and the first sub-pixel electrode 1210 may be configured to emit light of a first color. The width W1 of the opening 190OP of the insulating layer 190 may correspond to the width of an emission area of the first light-emitting diode LED1.

The first intermediate layer 1220 may include a first emission layer 1222 as illustrated in FIG. 4. The first intermediate layer 1220 may include a common layer disposed between the first sub-pixel electrode 1210 and the first emission layer 1222 and/or between the first emission layer 1222 and the opposite electrode 1230. Hereinafter, a common layer between the first sub-pixel electrode 1210 and the first emission layer 1222 is referred to as a first common layer 1221, and a common layer between the first emission layer 1222 and the opposite electrode 1230 is referred to as a second common layer 1223.

The first emission layer 1222 may include a polymer organic material or a low-molecular weight organic material configured to emit light having a preset color (e.g., red, green, or blue). In another embodiment, the first emission layer 1222 may include an inorganic material or quantum dots.

The first common layer 1221 may include a hole transport layer (HTL) and/or a hole injection layer (HIL). The second common layer 1223 may include an electron transport layer (ETL) and/or an electron injection layer (EIL). The first common layer 1221 and the second common layer 1223 may each include an organic material.

Referring to FIG. 3, an upper surface 1220at of the first portion 1220a of the first intermediate layer 1220 may include a flat surface, and an upper surface 1220bt of the second portion 1220b may include a slope surface which slopes toward an upper surface 100t of the substrate 100 with respect to an extension direction of the second portion 1220b, for example, a direction from the center of the first intermediate layer 1220 to the peripheral portion. For example, a distance between the slope surface and the upper surface 100t of the substrate 100 may decrease in the extension direction of the second portion 1220b. Expressed another way, the distance between the slope surface and the upper surface 100t of the substrate 100 may decrease in a direction from the center of the first intermediate layer 1220 to the peripheral portion.

The flat surface of the first portion 1220a of the first intermediate layer 1220 may be sloped (e.g., declined) at an angle of about 0° to about 15° toward the upper surface 100t of the substrate 100. In other words, the flat surface of the first portion 1220a of the first intermediate layer 1220 may be inclined at an angle of about 0° to about 15° with respect to a virtual plane L1 parallel to the upper surface 100t of the substrate 100.

The slope surface of the second portion 1220b of the first intermediate layer 1220 may be sloped (e.g., declined) at an angle θ of about 15° to about 45° toward the upper surface 100t of the substrate 100. In other words, the slope surface of the second portion 1220b of the first intermediate layer 1220 may be sloped (e.g., inclined) at an angle θ of about 15° to about 45° with respect to the virtual plane L1 parallel to the upper surface 100t of the substrate 100. The slope surface of the second portion 1220b of the first intermediate layer 1220 may have a gentle slope with respect to the upper surface 100t of the substrate 100.

In an embodiment, the upper surface 1220bt of the second portion 1220b of the first intermediate layer 1220 may include a slope surface of a preset angle. However, the disclosure is not limited thereto. In another embodiment, the upper surface 1220bt of the second portion 1220b may include slope surfaces having different respective angles. As an example, the slope angles of the slope surfaces may become smaller in a direction from the periphery to the center.

In an embodiment, a vertical distance from the upper surface 100t of the substrate 100 to the upper surface 1220at of the first portion 1220a of the first intermediate layer 1220 may be greater than a vertical distance from the upper surface 100t of the substrate 100 to the upper surface 1220bt of the second portion 1220b of the first intermediate layer 1220. In other words, a vertical distance h1 from the virtual plane L1 parallel to the upper surface 100t of the substrate 100 to the upper surface of the first portion 1220a of the first intermediate layer 1220 may be greater than a vertical distance h2 from the virtual plane L1 to the upper surface of the second portion 1220b of the first intermediate layer 1220.

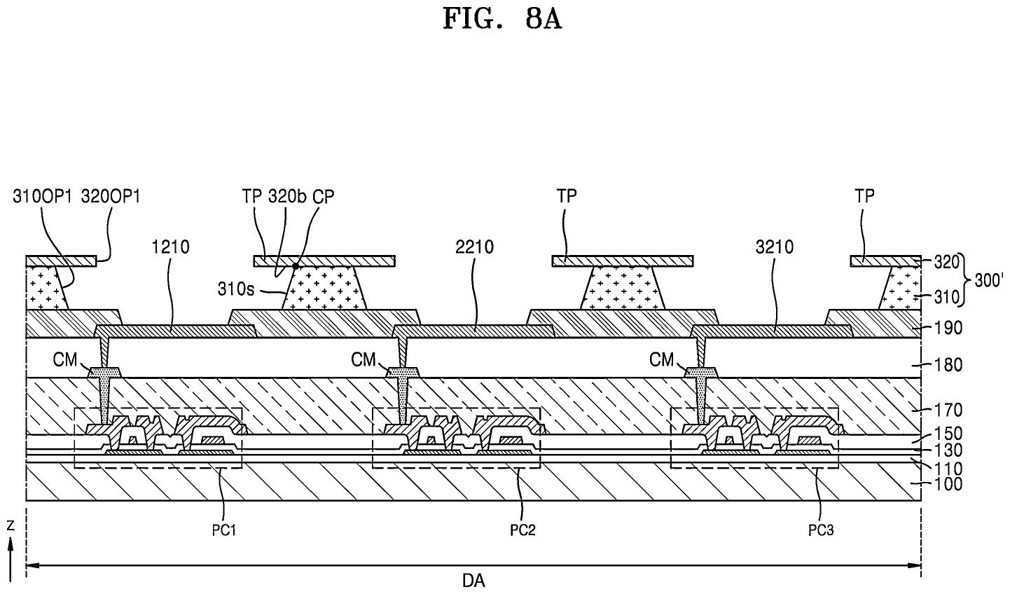

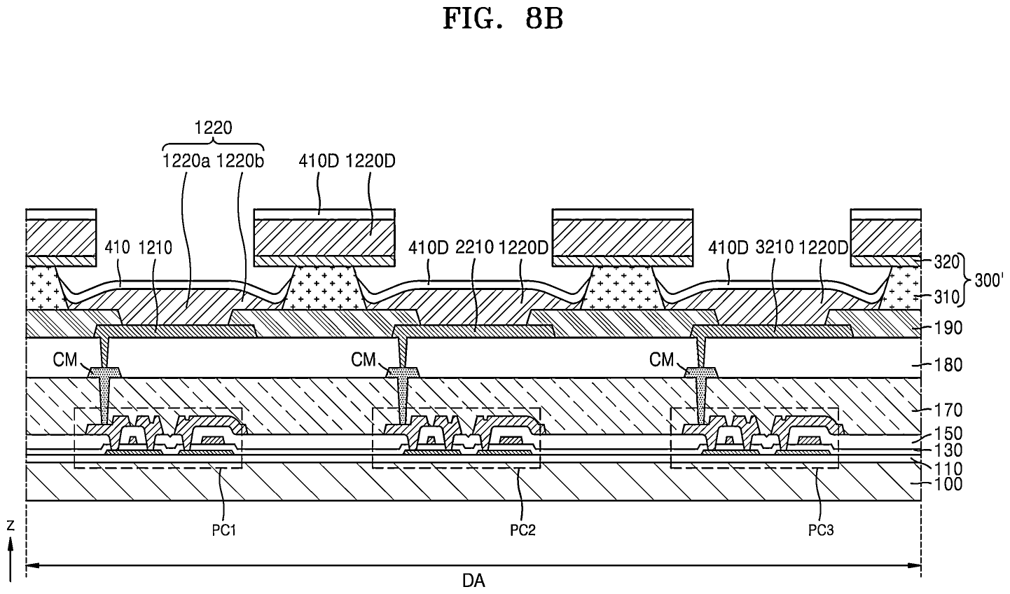

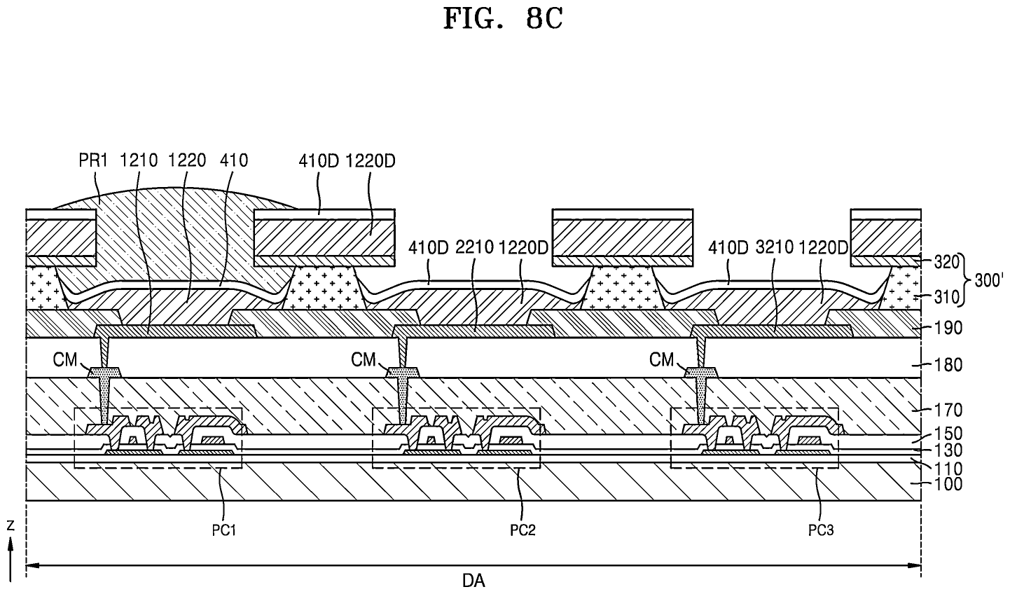

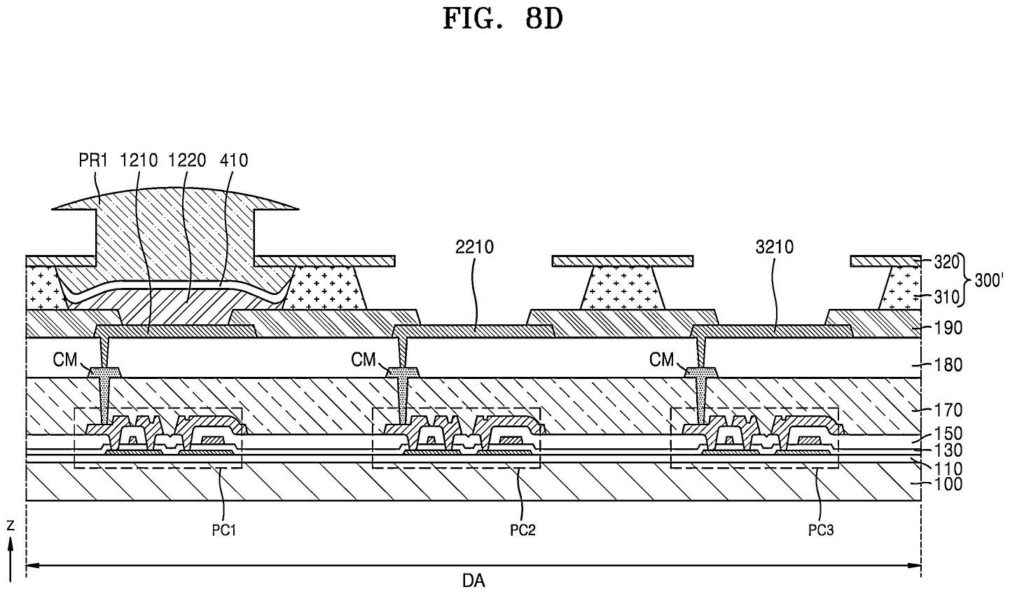

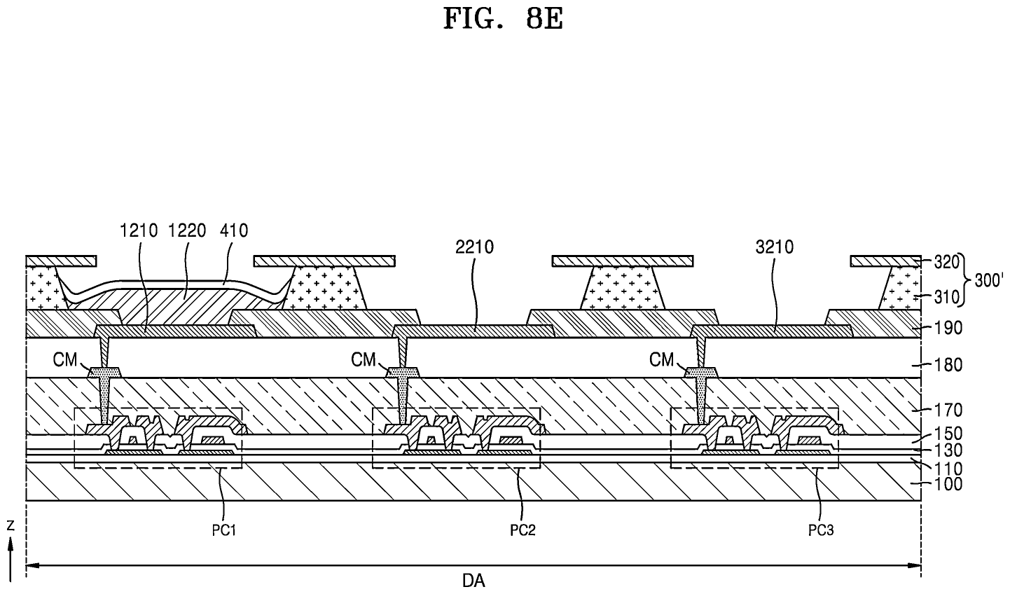

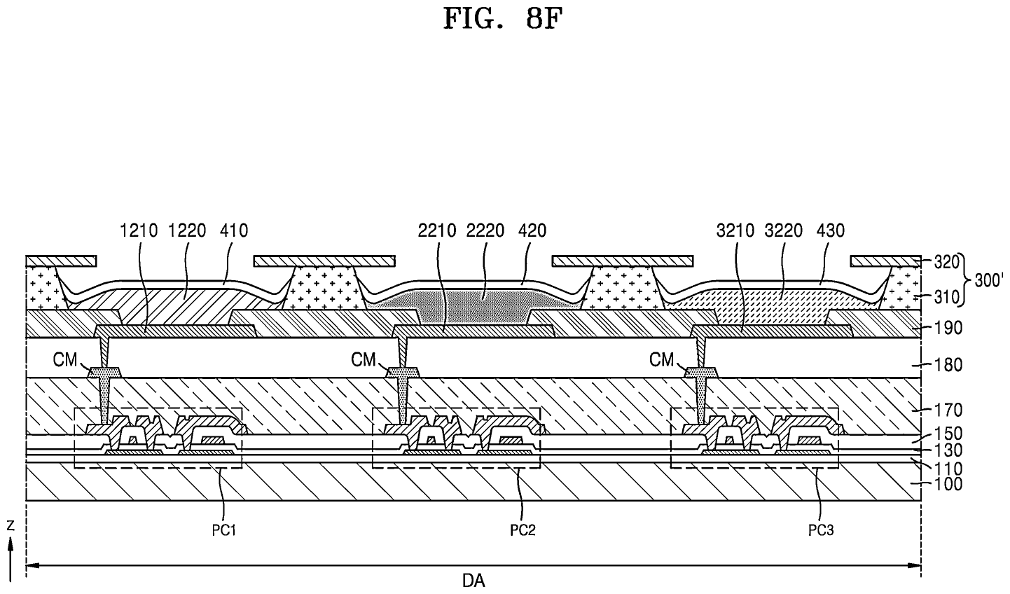

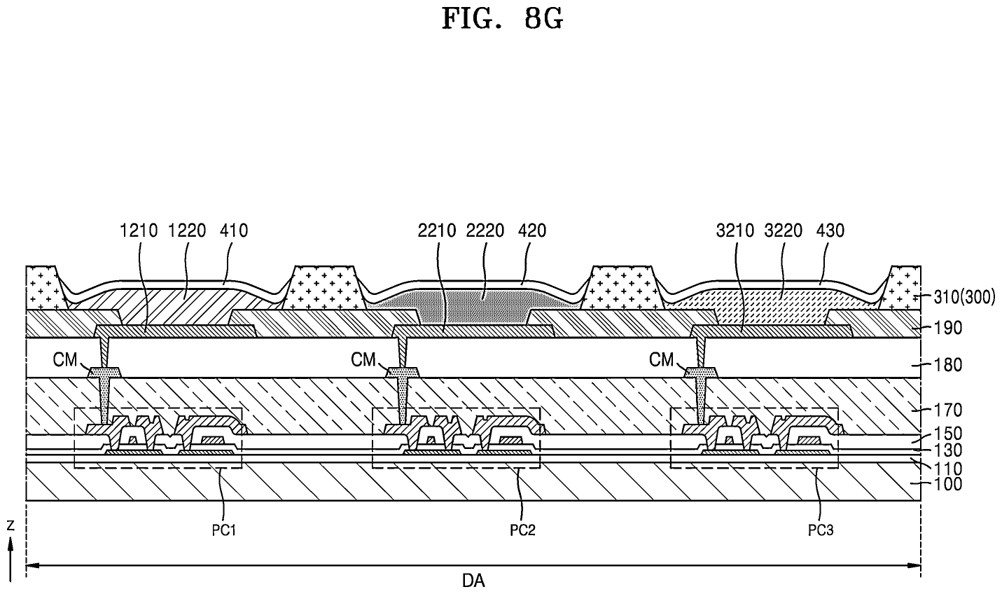

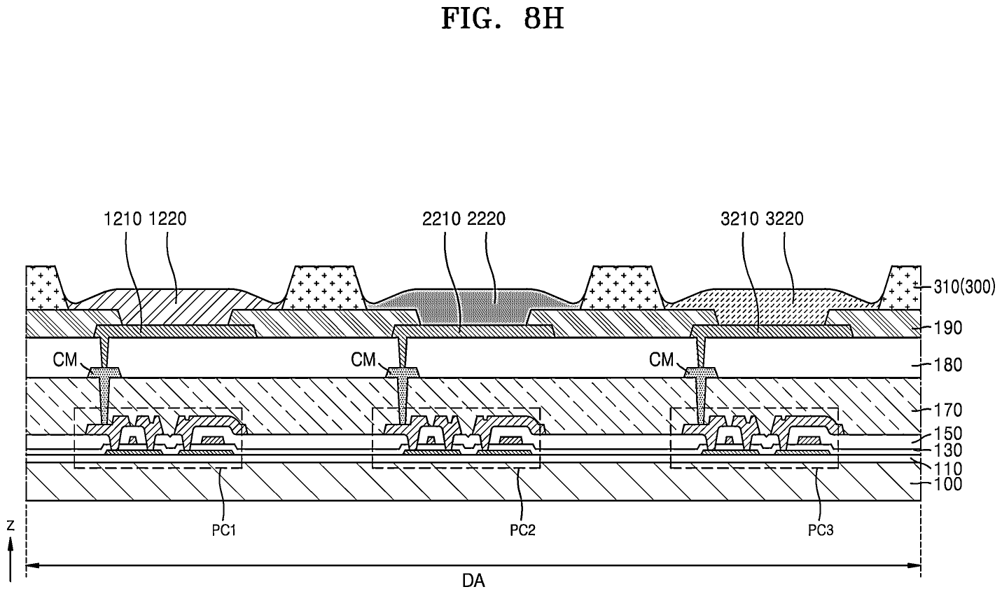

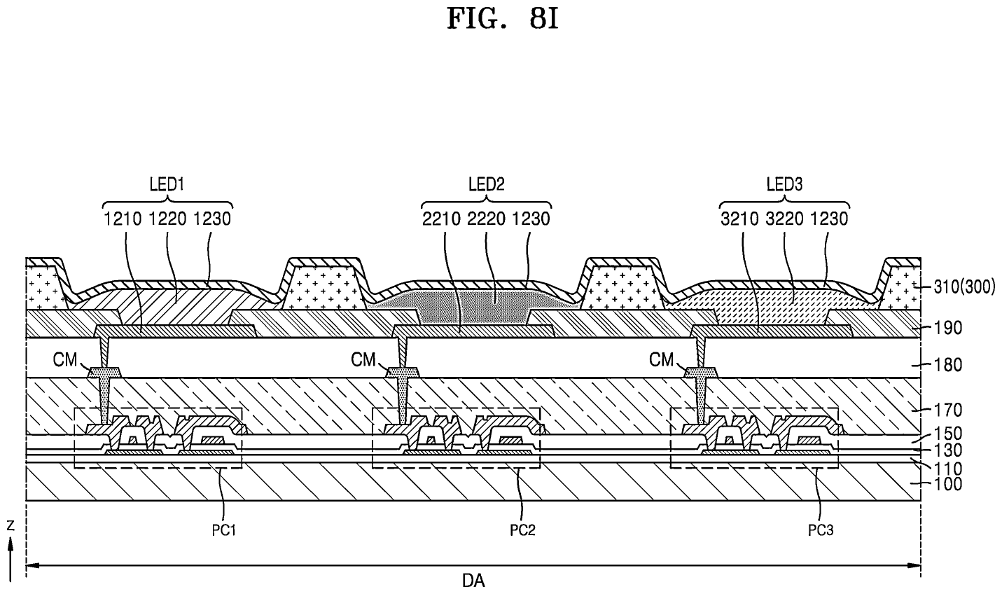

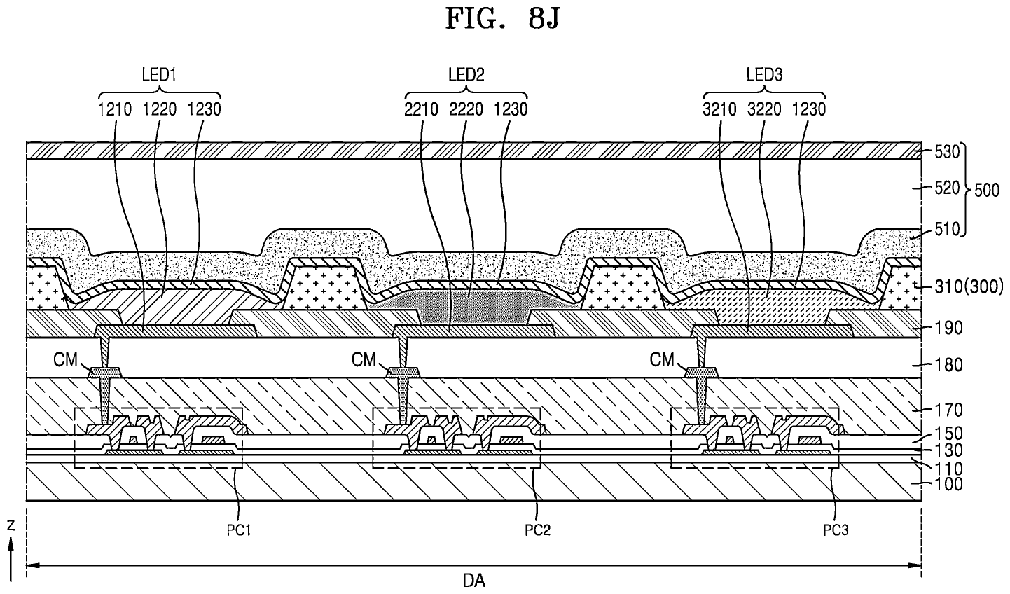

The slope structure of the upper surface 1220bt of the second portion 1220b of the first intermediate layer 1220 may be formed by a tip structure of a preliminary conductive bank layer 300′ described herein with reference to FIGS. 8A and 8B.

In an embodiment, as illustrated in FIG. 3, an edge 1220e of the first intermediate layer 1220 may be in contact with a lateral surface 300s of the conductive bank layer 300. However, the disclosure is not limited thereto. In another embodiment, as illustrated in FIG. 5, the edge 1220e of the first intermediate layer 1220 may be arranged such that the edge 1220e is adjacent to the lateral surface 300s of the conductive bank layer 300. In this case, for example, the edge 1220e of the first intermediate layer 1220 may be in contact with an upper surface 190t of the insulating layer 190. As an example, in an embodiment, the conductive bank layer 300 and the first intermediate layer 1220 may be formed such that a shortest distance between the lateral surface 300s of the conductive bank layer 300 and the edge 1220e of the first intermediate layer 1220 is 1 μm or less. The term “adjacent” used herein may refer to an element being next to another element, with or without being in contact with the other element. For example, in some cases, adjacent elements may be in contact with one another. In some other examples, adjacent elements may be near one another (e.g., spaced apart by a threshold distance or less).

The opposite electrode 1230 may include a conductive material having a low work function. As an example, the opposite electrode 1230 may include a (semi) transparent layer including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. In some aspects, the opposite electrode 1230 may further include a layer on the (semi) transparent layer, the layer including ITO, IZO, ZnO, or In₂O₃.

The opposite electrode 1230 may be integrally formed in the display area DA of the substrate 100. The opposite electrode 1230 may continuously extend such that the opposite electrode 1230 covers the first intermediate layer 1220 and the conductive bank layer 300. The opposite electrode 1230 may further extend beyond the edge of the first intermediate layer 1220 and be in direct contact with the conductive bank layer 300. As an example, as illustrated in FIGS. 3 and 5, the opposite electrode 1230 may be in direct contact with the upper surface of the first intermediate layer 1220, the upper surface of the conductive bank layer 300, and at least a portion of the lateral surface 300s of the conductive bank layer 300, for example, a portion of the lateral surface 300s of the conductive bank layer 300 on which the first intermediate layer 1220 is not disposed.

A capping layer (not illustrated) may be further disposed on the opposite electrode 1230. The opposite electrode 1230 may be protected by the capping layer disposed thereon. The capping layer may be an organic capping layer including an organic material, an inorganic capping layer including an inorganic material, or a composite capping layer including an organic material and an inorganic material. In an embodiment, the capping layer may be omitted.

A first inorganic encapsulation layer 510 may be disposed on the opposite electrode 1230. The first inorganic encapsulation layer 510 may be entirely formed in the display area DA of the substrate 100 and may extend toward the non-display area NDA (see FIGS. 1A and 1B). The first inorganic encapsulation layer 510 may overlap the first light-emitting diode LED1 and be configured to protect the first light-emitting diode LED1. As an example, as illustrated in FIGS. 3 and 5, the first inorganic encapsulation layer 510 may continuously overlap the first light-emitting diode LED1 and the conductive bank layer 300.

The first inorganic encapsulation layer 510 may include at least one inorganic insulating material from among aluminum oxide, titanium oxide, tantalum oxide, hafnium oxide, zinc oxide, silicon oxide, silicon nitride, and silicon oxynitride and be deposited using chemical vapor deposition.

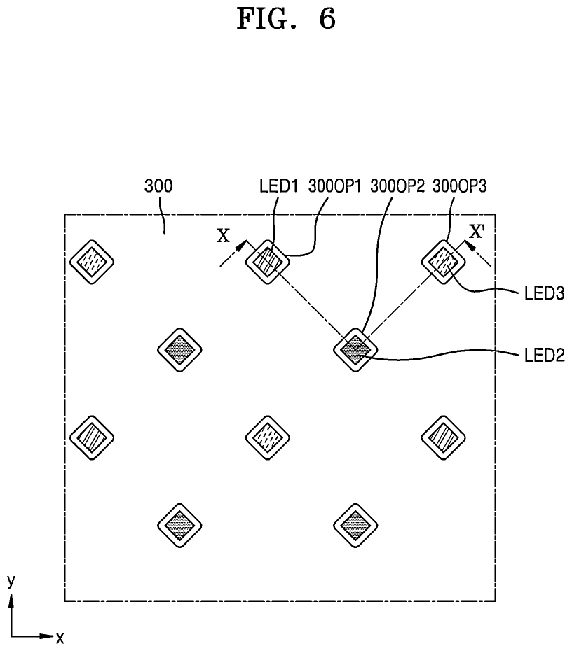

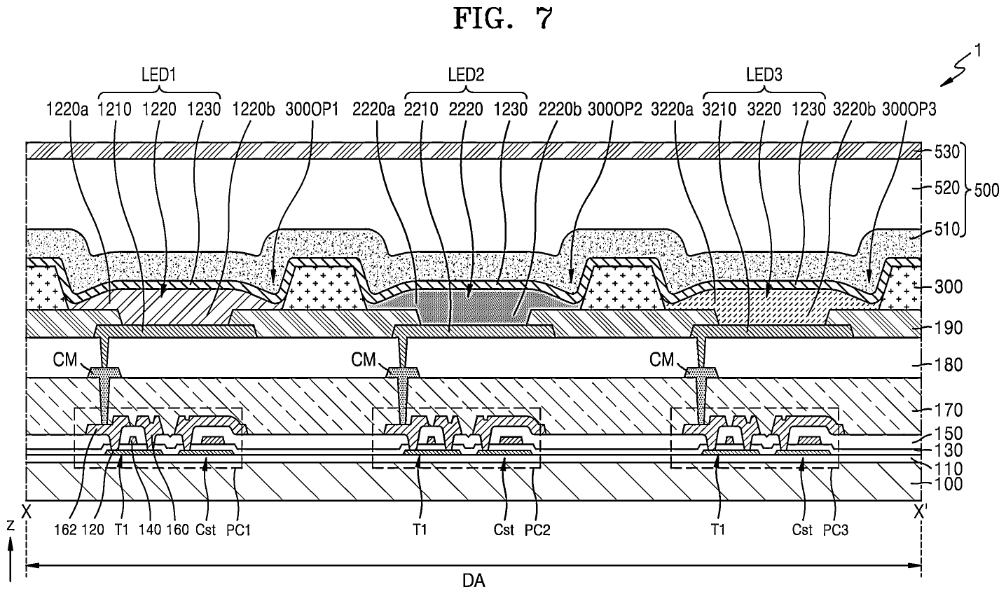

FIG. 6 is a plan view of the display apparatus according to an embodiment, and FIG. 7 is a cross-sectional view of the display apparatus, taken along line X-X′ of FIG. 6 according to an embodiment.

Referring to FIGS. 6 and 7, as illustrated in FIG. 6, the conductive bank layer 300 may include openings, for example, first to third openings 300OP1, 300OP2, and 300OP3 respectively corresponding to first to third sub-pixels. The first to third openings 300OP1, 300OP2, and 300OP3 may be arranged such that the first to third openings 300OP1, 300OP2, and 300OP3 are apart from each other, and the conductive bank layer 300 may have a netting structure in a plan view.

Referring to FIG. 6, first to third light-emitting diodes LED1, LED2, and LED3 may be respectively disposed in the first to third openings 300OP1, 300OP2, and 300OP3 of the conductive bank layer 300.

Referring to FIG. 7, the first to third light-emitting diodes LED1, LED2, and LED3 over the substrate 100 may be respectively electrically connected to first to third sub-pixel circuits PC1, PC2, and PC3.

The first to third sub-pixel circuits PC1, PC2, and PC3 may have substantially the same structure. As an example, the structures of the second and third sub-pixel circuits PC2 and PC3 may be the same as the structure of the first sub-pixel circuit PC1. With regard to this, it is illustrated in FIG. 7 that each of the second and third sub-pixel circuits PC2 and PC3 includes the first transistor T1 and the storage capacitor Cst.

The first to third light-emitting diodes LED1, LED2, and LED3 may have substantially the same structure. As described herein with reference to FIGS. 3 to 5, the first light-emitting diode LED1 illustrated in FIG. 7 may include a stack structure of the first sub-pixel electrode 1210, the first intermediate layer 1220, and the opposite electrode 1230 disposed in a first opening 310OP1 of the conductive bank layer 300. The first intermediate layer 1220 may include the first portion 1220a arranged in the center of the first intermediate layer 1220, and further, the second portion 1220b extending peripherally from the first portion 1220a. The upper surface of the second portion 1220b of the first intermediate layer 1220 may include a slope surface gently sloped (e.g., declined) toward the upper surface of the substrate 100 with respect to the extension direction of the second portion 1220b, for example, a direction from the center of the first intermediate layer 1220 to the peripheral portion.

The second light-emitting diode LED2 may include a stack structure of a second sub-pixel electrode 2210, a second intermediate layer 2220, and the opposite electrode 1230 disposed in a second opening 310OP2 of the conductive bank layer 300. The second intermediate layer 2220 may include a first portion 2220a arranged in the center of the second intermediate layer 2220, and the second intermediate layer 2220 may include the second portion 2220b extending peripherally from the first portion 2220a. The upper surface of the second portion 2220b of the second intermediate layer 2220 may include a slope surface gently sloped (e.g., declined) toward the upper surface of the substrate 100 with respect to the extension direction of the second portion 2220b, for example, a direction from the center of the second intermediate layer 2220 to the peripheral portion.

The third light-emitting diode LED3 may include a stack structure of a third sub-pixel electrode 3210, a third intermediate layer 3220, and the opposite electrode 1230 disposed in a third opening 310OP3 of the conductive bank layer 300. The third intermediate layer 3220 may include a first portion 3220a arranged in the center of the third intermediate layer 3220, and the second portion 3220b extending peripherally from the first portion 3220a. The upper surface of the second portion 3220b of the third intermediate layer 3220 may include a slope surface gently sloped (e.g., declined) toward the upper surface of the substrate 100 with respect to the extension direction of the second portion 3220b, for example, a direction from the center of the third intermediate layer 3220 to the peripheral portion.

The second light-emitting diode LED2 and the third light-emitting diode LED3 may include substantially the same structure and material except that the emission layer of the second intermediate layer and the emission layer of the third intermediate layer are configured to emit light of colors different from a color of light emitted from the emission layer of the first intermediate layer, and the emission layer of the second intermediate layer and the emission layer of the third intermediate layer include materials configured to emit light of colors different from the color of the light emitted from a material of the emission layer of the first intermediate layer. In other words, the structure of the cross-section corresponding to each of the second light-emitting diode LED2 and the third light-emitting diode LED3 is substantially the same or similar to the structure described herein with reference to FIGS. 3 to 5.

The opposite electrode 1230 may continuously extend such that the opposite electrode 1230 covers the first intermediate layer 1220 of the first light-emitting diode LED1, the second intermediate layer 2220 of the second light-emitting diode LED2, the third intermediate layer 3220 of the third light-emitting diode LED3, and the conductive bank layer 300. The opposite electrode 1230 may extend to pass the edge of each of the first intermediate layer 1220, the second intermediate layer 2220, and the third intermediate layer 3220 and be in direct contact with the conductive bank layer 300. As an example, as illustrated in FIG. 7, the opposite electrode 1230 may be in direct contact with the upper surface of the first intermediate layer 1220, the upper surface of the second intermediate layer 2220, the upper surface of the third intermediate layer 3220, the upper surface of the conductive bank layer 300, and at least a portion of the lateral surface 300s of the conductive bank layer 300, for example, a portion of the lateral surface 300s of the conductive bank layer 300 on which the first intermediate layer 1220, the second intermediate layer 2220, and the third intermediate layer 3220 are not disposed. The opposite electrode 1230 may be electrically connected to the auxiliary line VSL (see FIG. 2) through the conductive bank layer 300.

According to an embodiment, a contact area between the opposite electrode 1230 and the conductive bank layer 300 is sufficiently secured, which may prevent deterioration in display quality caused by a voltage drop of the opposite electrode 1230 of a large-sized display apparatus 1. Accordingly, the display apparatus 1 having high display quality may be provided.

An encapsulation layer 500 may include a first inorganic encapsulation layer 510, an organic encapsulation layer 520 on the first inorganic encapsulation layer 510, and a second inorganic encapsulation layer 530 on the organic encapsulation layer 520. The encapsulation layer 500 may overlap the first light-emitting diode LED1, the second light-emitting diode LED2, and the third light-emitting diode LED3, and protect the first to third light-emitting diodes LED1, LED2, and LED3. The encapsulation layer 500 may continuously overlap the first to third light-emitting diodes LED1, LED2, and LED3, and the conductive bank layer 300. As an example, the first inorganic encapsulation layer 510 may continuously overlap the first to third light-emitting diodes LED1, LED2, and LED3, and the conductive bank layer 300.

The organic encapsulation layer 520 may include a polymer-based material. The polymer-based material may include an acryl-based resin, an epoxy-based resin, polyimide, and polyethylene. In an embodiment, the organic encapsulation layer 520 may include acrylate.

The second inorganic encapsulation layer 530 may include at least one inorganic insulating material from among aluminum oxide, titanium oxide, tantalum oxide, hafnium oxide, zinc oxide, silicon oxide, silicon nitride, and silicon oxynitride.

FIGS. 8A to 8J are schematic cross-sectional views corresponding to a process of manufacturing a display apparatus according to an embodiment and show a process of manufacturing the display apparatus of FIG. 7. A method of manufacturing the display apparatus according to an embodiment is described with reference to FIGS. 8A to 8J.

In the descriptions of the method and processes herein, the operations may be performed in a different order than the order shown and/or described, or the operations may be performed in different orders or at different times. Certain operations may also be left out of the method and processes, one or more operations may be repeated, or other operations may be added. Descriptions that an element “may be disposed,” “may be formed,” “may be etched,” “may be removed” and the like include methods, processes, and techniques for disposing, forming, positioning, etching, and modifying the element, and the like in accordance with example aspects described herein.

Referring to FIG. 8A, the method may include forming the first sub-pixel electrode 1210, the second sub-pixel electrode 2210, and the third sub-pixel electrode 3210 on the second organic insulating layer 180, and the method may include forming an insulating layer 190 covering the lateral surface (that is, the edge) of each of the first sub-pixel electrode 1210 to the third sub-pixel electrode 3210. The insulating layer 190 may include openings respectively overlapping the first sub-pixel electrode 1210 to the third sub-pixel electrode 3210.

The method may include forming the preliminary conductive bank layer 300′ on the insulating layer 190. The preliminary conductive bank layer 300′ may include conductive layers having different etching selectivities. In an embodiment, the preliminary conductive bank layer 300′ may include a first conductive layer 310 and a second conductive layer 320 on the first conductive layer 310. The first conductive layer 310 and the second conductive layer 320 may include metals having different respective etching selectivities. For example, the etching selectivity of a metal included in the first conductive layer 310 may be different from the etching selectivity of a metal included in the second conductive layer 320. In an embodiment, the first conductive layer 310 may include a layer including aluminum (Al), and the second conductive layer 320 may include a layer including titanium (Ti).

Although it is illustrated in FIG. 8A that the preliminary conductive bank layer 300′ includes two conductive layers, the disclosure is not limited thereto. In another embodiment, the preliminary conductive bank layer 300′ may include the first conductive layer 310, the second conductive layer 320 on the first conductive layer 310, and a third conductive layer under the first conductive layer 310.

The method may include forming the preliminary conductive bank layer 300′ by etching a preliminary first conductive layer (not illustrated) and a preliminary second conductive layer (not illustrated) having different etching selectivities. The method may include forming the first conductive layer 310 and the second conductive layer 320 by removing a portion of the preliminary first conductive layer and a portion of the preliminary second conductive layer. In this case, openings may be formed in the first conductive layer 310, wherein the openings overlap the first sub-pixel electrode 1210 to the third sub-pixel electrode 3210. Openings may be formed in the second conductive layer 320, and the openings may respectively overlap the first sub-pixel electrode 1210 to the third sub-pixel electrode 3210.

As an example, the method may include forming the first opening 310OP1 overlapping the first sub-pixel electrode 1210 in the first conductive layer 310, and the method may include forming a first opening 320OP2 overlapping the first sub-pixel electrode 1210 in the second conductive layer 320. The width of the opening of the second conductive layer 320 may be greater than the width of the opening of the first conductive layer 310. As an example, the width of the first opening 320OP1 of the second conductive layer 320 may be greater than the width of the first opening 310OP1 of the first conductive layer 310.

In an embodiment, the preliminary conductive bank layer 300′ may include an undercut structure in a cross-sectional view. As an example, the second conductive layer 320 may include a tip TP extending (i.e., protruding) in a direction (e.g., a lateral direction) from a point CP where a lateral surface 310s of the first conductive layer 310 meets a bottom surface 320b of the second conductive layer 320.

Referring to FIG. 8B, the method may include forming the first intermediate layer 1220 and a first sacrificial layer 410 each overlapping the first sub-pixel electrode 1210. In an embodiment, the method may include forming the first intermediate layer 1220 by a deposition method such as, for example, thermal deposition. The first sacrificial layer 410 may be configured to protect the first intermediate layer 1220. The first sacrificial layer 410 may include a metal material. As an example, the first sacrificial layer 410 may include aluminum (Al).

The method may include depositing the first intermediate layer 1220 and the first sacrificial layer 410 without a separate mask. A deposition material for forming the first intermediate layer 1220 may form the preliminary conductive bank layer 300′, the second sub-pixel electrode 2210, or a first dummy intermediate layer 1220D overlapping the third sub-pixel electrode 3210. In some aspects, a deposition material for forming the first sacrificial layer 410 may form the preliminary conductive bank layer 300′, the second sub-pixel electrode 2210, or a first dummy sacrificial layer 410D overlapping the third sub-pixel electrode 3210. The first intermediate layer 1220 and the first dummy intermediate layer 1220D may be separated and spaced apart from each other. The first sacrificial layer 410 and the first dummy sacrificial layer 410D may be separated and spaced apart from each other. The first intermediate layer 1220 and the first dummy intermediate layer 1220D may include the same material and/or the same number of conductive layers (e.g., a first common layer, an emission layer, and a second common layer). The first sacrificial layer 410 and the first dummy sacrificial layer 410D may include the same material.

An incident angle of a deposition material forming the first intermediate layer 1220 may be affected (e.g., limited) by the undercut structure of the preliminary conductive bank layer 300′. Specifically, for example, the first intermediate layer 1220 may be deposited inside the first opening 310OP of the first conductive layer 310 of the preliminary conductive bank layer 300′ and may include the first portion 1220a and the second portion 1220b extending peripherally from the first portion 1220a. In this case, due to the tip TP of the second conductive layer 320 of the preliminary conductive bank layer 300′, the upper surface of the second portion 1220b of the first intermediate layer 1220 adjacent to the preliminary conductive bank layer 300 may include a slope surface sloped (e.g., declined) toward the upper surface of the substrate 100 with respect to an extension direction of the second portion 1220b. In an example, the extension direction of the second portion 1220b may be a direction from the center of the first intermediate layer 1220 toward the peripheral portion.

Referring to FIGS. 8C, 8D, and 8E, the method may include forming a first photoresist pattern PR1 covering the first intermediate layer 1220 and the first sacrificial layer 410. Next, the method may include etching the first dummy intermediate layer 1220D and the first dummy sacrificial layer 410D using the first photoresist pattern PR1 as a mask. In this case, the etching process may be performed as dry etching and/or wet etching. In an example, the etching process may include removing all of the first dummy intermediate layer 1220D and the first dummy sacrificial layer 410D that are not completely covered by the first photoresist pattern PR1.

Then, the method may include removing the first photoresist pattern PR1.

Referring to FIG. 8F, the second intermediate layer 2220 and the second sacrificial layer 420 may each overlap the second sub-pixel electrode 2120, and the third intermediate layer 3220 and a third sacrificial layer 430 may each overlap the third sub-pixel electrode 3120. The method may include sequentially removing the second intermediate layer 2220, the second sacrificial layer 420, the third intermediate layer 3220, and the third sacrificial layer 430. As an example, the method may include forming the second intermediate layer 2220 and the second sacrificial layer 420, and the method may include then forming the third intermediate layer 3220 and the third sacrificial layer 430. The forming of the second intermediate layer 2220 and the second sacrificial layer 420 and the forming of the third intermediate layer 3220 and the third sacrificial layer 430 may be performed by substantially the same process as the process of forming the first intermediate layer 1220 and the first sacrificial layer 410 described with reference to FIGS. 8B to 8E.

In an embodiment, the first sacrificial layer 410, the second sacrificial layer 420, and the third sacrificial layer 430 may include the same material. As an example, the first sacrificial layer 410, the second sacrificial layer 420, and the third sacrificial layer 430 may include aluminum (Al). The disclosure is not limited thereto. In another embodiment, the first sacrificial layer 410, the second sacrificial layer 420, and the third sacrificial layer 430 may respectively include different metal materials.

Referring to FIG. 8G, the method may include forming the conductive bank layer 300 by removing the second conductive layer 320 of the preliminary conductive bank layer 300′. The method may include removing second conductive layer 320 by etching, and the etching process may be performed by dry etching or may be performed by a combination of dry etching and wet etching. In this case, the first intermediate layer 1220, the second intermediate layer 2220, and the third intermediate layer 3220 may be respectively protected by the first sacrificial layer 410, the second sacrificial layer 420, and the third sacrificial layer 430. The first conductive layer 310 from which the second conductive layer 320 is removed may correspond to the conductive bank layer 300.

Referring to FIG. 8H, the method may include removing the first sacrificial layer 410, the second sacrificial layer 420, and the third sacrificial layer 430 by etching. In an embodiment, the method may include simultaneously performing processes of removing the first sacrificial layer 410, the second sacrificial layer 420, and the third sacrificial layer 430. Alternatively, the method may include sequentially performing the processes of removing the first sacrificial layer 410, the second sacrificial layer 420, and the third sacrificial layer 430. In some cases, if the etching process is performed by dry etching, the first to third intermediate layers 1220, 2220, and 3220 may be damaged by plasma. Accordingly, to prevent or reduce damage to the first to third intermediate layers 1220, 2220, and 3220, the method may include performing the etching process by wet etching.

Then, method may include drying the substrate 100 by heat-treating the substrate 100 at temperature of 100° C. (or about 100° C.) or below.

Referring to FIG. 8I, the method may include forming the opposite electrode 1230. In an embodiment, the method may include forming the opposite electrode 1230 by a deposition method such as, for example, thermal deposition. The method may include continuously forming the opposite electrode 1230 such that the opposite electrode 1230 is continuous on the first intermediate layer 1220, the second intermediate layer 2220, the third intermediate layer 3220, and the conductive bank layer 300. A stack structure of the first sub-pixel electrode 1210, the first intermediate layer 1220, and the opposite electrode 1230 may correspond to the first light-emitting diode LED1. A stack structure of the second sub-pixel electrode 2210, the second intermediate layer 2220, and the opposite electrode 1230 may correspond to the second light-emitting diode LED2. A stack structure of the third sub-pixel electrode 3210, the third intermediate layer 3220, and the opposite electrode 1230 may correspond to the third light-emitting diode LED3.

Referring to FIG. 8J, the method may include forming the encapsulation layer 500 on the opposite electrode 1230. The method may include sequentially forming the first inorganic encapsulation layer 510, the organic encapsulation layer 520, and the second inorganic encapsulation layer 530.

According to embodiments, a display apparatus with high quality and a method of manufacturing the display apparatus may be implemented. However, the scope of the disclosure is not limited by this effect.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first sub-pixel electrode over the substrate;
a conductive bank layer disposed on the first sub-pixel electrode and comprising a first opening overlapping the first sub-pixel electrode;
a first intermediate layer overlapping the first sub-pixel electrode and contacting the first sub-pixel electrode through the first opening of the conductive bank layer; and
an opposite electrode covering the first intermediate layer and the conductive bank layer,
wherein the first intermediate layer comprises a first portion in a center of the first intermediate layer and a second portion extending peripherally from the first portion, and
an upper surface of the second portion comprises a slope surface sloped toward an upper surface of the substrate with respect to an extension direction of the second portion.

2. The display apparatus of claim 1, wherein the slope surface of the second portion is inclined at an angle of about 15° to about 45° with respect to the upper surface of the substrate.

3. The display apparatus of claim 1, wherein a vertical distance from the upper surface of the substrate to an upper surface of the first portion of the first intermediate layer is greater than a vertical distance from the upper surface of the substrate to the upper surface of the second portion of the first intermediate layer.

4. The display apparatus of claim 1, further comprising an insulating layer disposed between a peripheral portion of the first sub-pixel electrode and the conductive bank layer and comprising an opening overlapping the first opening.

5. The display apparatus of claim 4, wherein at least a portion of the first intermediate layer is disposed on an upper surface of the insulating layer.

6. The display apparatus of claim 4, wherein a width of the first opening of the conductive bank layer is greater than a width of the opening of the insulating layer.

7. The display apparatus of claim 1, wherein an edge of the first intermediate layer is in contact with the conductive bank layer.

8. The display apparatus of claim 1, wherein an edge of the first intermediate layer is adjacent to the conductive bank layer.

9. The display apparatus of claim 1, wherein the opposite electrode continuously covers at least a portion of an upper surface of the conductive bank layer, at least a portion of a lateral surface of the conductive bank layer, and an upper surface of the first intermediate layer.

10. The display apparatus of claim 1, further comprising:
a second sub-pixel electrode over the substrate; and
a second intermediate layer overlapping the second sub-pixel electrode and contacting the second sub-pixel electrode through a second opening of the conductive bank layer,
wherein the opposite electrode continuously covers the first intermediate layer, the conductive bank layer, and the second intermediate layer.

11. A method of manufacturing a display apparatus, the method comprising:
forming a first sub-pixel electrode over a substrate;
forming a conductive bank layer comprising a first opening overlapping the first sub-pixel electrode;
forming a first intermediate layer overlapping the first sub-pixel electrode and contacting the first sub-pixel electrode through the first opening of the conductive bank layer; and
forming an opposite electrode covering the first intermediate layer and the conductive bank layer,
wherein the first intermediate layer comprises a first portion in a center of the first intermediate layer and a second portion extending peripherally from the first portion, and
an upper surface of the second portion comprises a slope surface sloped toward an upper surface of the substrate with respect to an extension direction of the second portion.

12. The method of claim 11, further comprising forming an insulating layer disposed between a peripheral portion of the first sub-pixel electrode and the conductive bank layer and comprising an opening overlapping the first opening,
wherein a width of the first opening of the conductive bank layer is greater than a width of the opening of the insulating layer.

13. The method of claim 11, wherein the forming of the conductive bank layer comprises:
forming a preliminary conductive bank layer comprising a first conductive layer and a second conductive layer on the first conductive layer; and
removing the second conductive layer of the preliminary conductive bank layer,
wherein the second conductive layer comprises a tip extending in a direction from a point where a lateral surface of the first conductive layer meets a bottom surface of the second conductive layer.

14. The method of claim 13, wherein the removing of the second conductive layer is performed after the forming of the first intermediate layer.

15. The method of claim 11, wherein the forming of the first intermediate layer comprises:
forming the first intermediate layer and a first dummy intermediate layer;
forming a first sacrificial layer on the first intermediate layer, and forming a first dummy sacrificial layer on the first dummy intermediate layer;
forming a first photoresist pattern overlapping the first sub-pixel electrode;
etching the first dummy intermediate layer and the first dummy sacrificial layer using the first photoresist pattern as a mask; and
removing the first photoresist pattern.

16. The method of claim 15, further comprising removing the first sacrificial layer.

17. The method of claim 16, further comprising:
forming a second sub-pixel electrode over the substrate; and
forming a second intermediate layer overlapping the second sub-pixel electrode and contacting the second sub-pixel electrode through a second opening of the conductive bank layer,
wherein the opposite electrode continuously covers the first intermediate layer, the conductive bank layer, and the second intermediate layer.

18. The method of claim 17, wherein the forming of the second intermediate layer comprises:
forming the second intermediate layer and a second dummy intermediate layer;
forming a second sacrificial layer on the second intermediate layer, and forming a second dummy sacrificial layer on the second dummy intermediate layer;
forming a second photoresist pattern overlapping the second sub-pixel electrode;
etching the second dummy intermediate layer and the second dummy sacrificial layer using the second photoresist pattern as a mask; and
removing the second photoresist pattern.

19. The method of claim 18, further comprising removing the second sacrificial layer,
wherein the removing of the second sacrificial layer is simultaneously performed with the removing of the first sacrificial layer.

20. The method of claim 11, wherein an edge of the first intermediate layer is in contact with or adjacent to the conductive bank layer.
